(19) United States
(12) Patent Application Publication
(10) Pub. No.: US 2026/0339194 A1
(43) Pub. Date: Oct. 29, 2026

(54) NEURAL LITHOGRAPHY ON VECTOR GRAPHICS

(71) Applicants: SAMSUNG ELECTRONICS CO., LTD., Suwon-si (KR); The Board of Trustees of the Leland Stanford Junior University, Stanford, CA (US)

(72) Inventors: Sooyong Lee, Menlo Park, CA (US); Gordon Wetzstein, Palo Alto, CA (US); Guandao Yang, Palo Alto, CA (US); Gun-Yeal Lee, Palo Alto, CA (US); Seongtae Jeong, Suwon-si (KR); Suyeon Choi, Redwood City, CA (US)

(21) Appl. No.: 19/192,806

(22) Filed: Apr. 29, 2025

(51) Int. Cl. G03F 1/36; G03F 7/00

(52) U.S. Cl. CPC G03F 1/36; G03F 7/0005

(57) ABSTRACT

Provided is a mask manufacturing method. The method comprises obtaining layout data representing a candidate layout corresponding to a target pattern, wherein the candidate layout comprises a plurality of geometries; generating, based on the candidate layout, boundary data for the candidate layout, wherein the boundary data represents a boundary of each of the plurality of geometries; generating a frequency domain representation of the candidate layout based on transforming the candidate layout using normal vectors with respect to the boundary of each of the plurality of geometries; generating a modified layout based on the frequency domain representation of the candidate layout; and outputting final layout data representing the modified layout corresponding to the target pattern to be used to manufacture a mask.

### BACKGROUND

Fabrication layouts for device fabrication (e.g., electronic and optical device fabrication) indicate patterns that are to be formed on a chip. For example, a layout may include a large number of polygons that represent shapes of device structures. The polygons can be formed on an optical mask (or photomask) and used for lithography on the chip. Due to optical effects (e.g., diffraction) and other non-idealities, such as non-idealities associated with pattern etching, patterns actually formed on the chip differ from the layout patterns of the photomask (or “mask” for short). Correction procedures are used to compensate for non-idealities and subtle effects in photolithography and other aspects of device fabrication.

### SUMMARY

In general, the present disclosure is directed toward a design and device fabrication workflow that includes a differentiable optical proximity correction (OPC) process.

According to some implementations, the present disclosure is directed to a mask manufacturing method, comprising: obtaining layout data representing a candidate layout corresponding to a target pattern, wherein the candidate layout comprises a plurality of geometries; generating, based on the candidate layout, boundary data for the candidate layout, wherein the boundary data represents a boundary of each of the plurality of geometries; generating a frequency domain representation of the candidate layout based on transforming the candidate layout using normal vectors with respect to the boundary of each of the plurality of geometries; generating a modified layout based on the frequency domain representation of the candidate layout; and outputting final layout data representing the modified layout corresponding to the target pattern to be used to manufacture a mask.

According to some implementations, the present disclosure is directed to a system comprising one or more computers and one or more storage devices storing instructions that are operable, when executed by the one or more computers, to cause the one or more computers to perform mask manufacturing operations comprising: obtaining layout data representing a candidate layout corresponding to a target pattern, wherein the candidate layout comprises a plurality of geometries; generating, based on the candidate layout, boundary data for the candidate layout, wherein the boundary data represents a boundary of each of the plurality of geometries; generating a frequency domain representation of the candidate layout based on transforming the candidate layout using normal vectors with respect to the boundary of each of the plurality of geometries; generating a modified layout based on the frequency domain representation of the candidate layout; and outputting final layout data representing the modified layout corresponding to the target pattern to be used to manufacture a mask.

According to some implementations, the present disclosure is directed to a non-transitory computer storage medium encoded with instructions that, when executed by one or more computers, cause the one or more computers to perform mask manufacturing operations comprising: obtaining layout data representing a candidate layout corresponding to a target pattern, wherein the candidate layout comprises a plurality of geometries; generating, based on the candidate layout, boundary data for the candidate layout, wherein the boundary data represents a boundary of each of the plurality of geometries; generating a frequency domain representation of the candidate layout based on transforming the candidate layout using normal vectors with respect to the boundary of each of the plurality of geometries; generating a modified layout based on the frequency domain representation of the candidate layout; and outputting final layout data representing the modified layout corresponding to the target pattern to be used to manufacture a mask.

Generating the frequency domain representation of the candidate layout comprises operating directly on the layout data in a vector graphic format. Generating the frequency domain representation of the candidate layout comprises: for a geometry in the plurality of geometries having a curved shape, generating a piecewise linear approximation of the boundary of the geometry that comprises a plurality of linear segments that approximate the curved shape of the geometry; and computing a Fourier transform on the candidate layout using normal vectors with respect to the plurality of linear segments included in the piecewise linear approximation generated for each of the one or more of the plurality of geometries. Computing the Fourier transform on the candidate layout comprises: analytically computing the Fourier transform by, for each of the one or more of the plurality of geometries, computing a line integral for each of the plurality of linear segments included in the piecewise linear approximation generated for the geometry. Generating the modified layout based on the frequency domain representation of the candidate layout comprises: obtaining a resist image that is generated based on the frequency domain representation of the candidate layout, wherein the resist image comprises resist image intensity values at discrete spatial coordinates; applying a frequency transform on amplitude values of the resist image intensity values to generate a frequency domain representation of the resist image; applying an inverse frequency transform on the frequency domain representation of the resist image to generate amplitude values at continuous spatial coordinates; and generating, based on the amplitude values at continuous spatial coordinates, a continuous resist image that comprises resist image intensity values at the continuous spatial coordinates. The frequency transform comprises a discrete Fourier transform (DFT). The inverse frequency transform comprises an inverse discrete Fourier transform (iDFT). Obtaining the resist image comprises: generating an optical image based on the candidate layout; processing the optical image using a convolutional neural network (CNN) to generate the resist image intensity values included in the resist image. Generating the modified layout based on the frequency domain representation of the candidate layout comprises: evaluating a loss function that measures a difference between a contour in the continuous resist image and an edge of target pattern; and adjusting the candidate layout by backpropagation based on a gradient of the loss function. Outputting the final layout data representing the modified layout corresponding to the target pattern to be used to manufacture the mask comprises: transferring the final layout data as mask tape-out (MTO) design data. The method further comprises manufacture the mask by: preparing mask data based on the MTO design data; and performing, based on the mask data, exposure on a substrate for the mask. The method further comprises manufacturing a semiconductor chip using the mask.

It should be noted that the effects are not limited to those described above, and other effects of example embodiments will be apparent from the following description.

### BRIEF DESCRIPTION OF DRAWINGS

FIG. 1 is a diagram illustrating an example of a design and device fabrication workflow that includes a differentiable optical proximity correction (OPC) process.

FIG. 2 is a block diagram illustrating an example computer system that may be configured to perform operations included in a differentiable OPC process.

FIG. 3 is a flow diagram of an example process for differentiable OPC.

FIG. 4 is a flow diagram of an example process for generating an aerial image described in FIG. 3.

FIG. 5 is a flow diagram of an example process for generating a continuous resist image described in FIG. 3.

FIG. 6A-D show examples of illustrations of an edge of a target pattern and a contour of the target pattern.

FIG. 7 is a diagram illustrating an example computer system for implementing the present disclosure.

FIG. 8 illustrates an example computer system that includes an artificial intelligence (AI) accelerator for implementing the present disclosure.

FIG. 9 is a block diagram of an example environment in which differentiable OPC can be implemented.

### DETAILED DESCRIPTION

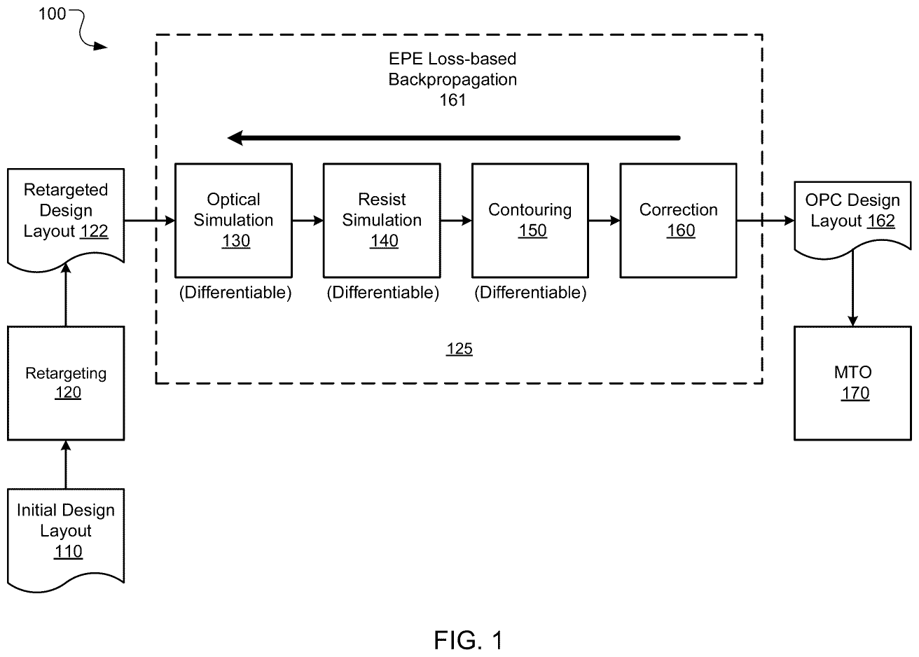

FIG. 1 is a diagram illustrating an example of a design and device fabrication workflow 100 that includes a differentiable optical proximity correction (OPC) process 125, according to some implementations of the present disclosure. As shown in FIG. 1, in an example of a design and device fabrication workflow 100, an initial design layout 110 that corresponds to a target pattern is obtained, e.g., from a server or a host computer operatively associated with a semiconductor manufacturing facility.

For example, the target pattern may be a circuit pattern to be formed on a substrate (e.g., a silicon wafer or another material surface) through an exposure process using a mask. The initial design layout 110 may be, for example, a design layout of a mask pattern to be formed on the mask to thereby form the target pattern. In other words, the mask pattern on the mask may be transferred to the substrate through the exposure process to form the target pattern on the substrate. The initial design layout can include any of a variety of geometries, e.g., geometries that have curved shapes, or geometries that have polygon shapes such as squares, rectangles, or triangles, or both. Due to characteristics of the exposure process, the target pattern and the design layout of the mask pattern may have different forms.

Retargeting 120 is performed based on predicted and/or measured differences between the initial design layout 110 and patterns formed on the substrate by etching. As a result, a retargeted design layout 122—that is, an adjusted design layout resulting from the performance of the retargeting 120 on the initial design layout 110—is generated as an adjustment of the initial design layout 110, e.g., with difference feature sizes, spacings, widths, and/or the like compared to the initial design layout 110. This adjustment can compensate, for example, for biases in the etching process.

The differentiable optical proximity correction (OPC) process 125 is performed on the retargeted design layout 122 to generate an OPC design layout 162—that is, a further adjusted design layout resulting from the performance of the differentiable OPC process 125 on the retargeted design layout 122. Compared to the retargeted design layout 122, the OPC design layout 162 is altered (e.g., optimized) to account for optical distortion, diffraction, and other optical effects that may occur in photolithography. In this regard, the retargeted design layout 122 may be referred to as a pre-OPC design layout, while the OPC design layout 162 may be referred to as a post-OPC design layout.

The OPC design layout 162 can be formed on a mask and used for subsequent device fabrication. In other words, a mask may be manufactured using the OPC design layout 162. For example, after performing the differentiable OPC process 125, the OPC design layout 162 obtained through the differentiable OPC process 125 may be communicated to another system as mask tape out (MTO) design data 170. In this regard, the MTO design data may be understood as mask design data, as corrected and verified by at least the retargeting 120 and the differentiable OPC process 125. Ultimately, a semiconductor chip may be manufactured using the mask.

In general, optical proximity correction (OPC) can be used to compensate for some non-idealities, e.g., non-idealities caused by optical effects (e.g., diffraction) or associated with pattern etching, to ensure that the pattern actually formed on the substrate stays as close to the target pattern as possible. Unlike the differentiable OPC process in the present disclosure, many other OPC methods may be hampered by technical limitations associated with the non-differentiable nature of those methods, resulting in relatively poor optimization of device features.

For example, an existing OPC workflow may use a rasterization operation as part of an optical simulation stage. The optical simulation stage involves rendering an image from design layout data, e.g., the retargeted design layout 122, to generate image data, e.g., an aerial image. After obtaining geometries of the design layout, a rasterization operation is performed based on the geometries to convert the geometries represented in data that has a vector graphic format (e.g., that includes spatial domain coordinates) to a rasterized image (e.g., that includes pixels). Due to the binary assignment that decides whether a pixel is covered by any geometry, a typical rasterization operation—and therefore the existing OPC workflow overall—is non-differentiable.

As will be described further below, unlike these existing OPC methods, the OPC process 125 included in the design and device fabrication workflow 100 does not involve any rasterization operation, and the OPC process 125 is differentiable. Implementations of the differentiable OPC process 125 described throughout this specification can realize one or more of the following advantages.

First, the differentiable OPC process 125 can reduce grid dependency to improve the accuracy of the post-OPC design layout and therefore, improve the quality of a final mask to be manufactured in accordance with the post-OPC design layout. In particular, the grid dependency of the differentiable OPC process 125 is reduced because the accuracy of the differentiable OPC process 125 is no longer constrained by the design grid unit, i.e., the minimum resolution unit of a layout design. The reduction of grid dependency largely alleviates common issues faced by existing OPC workflows where the accuracy of the post-OPC design layout is unexpectedly lowered because lithography critical dimension and/or contour prediction, hotspot detection, and/or layout correction results deviate by a very smaller distance, e.g., no greater than 1 nanometer (1 nm), e.g., due to alignment differences between the design layout and the design grid.

Second, the differentiable OPC process 125 can eliminate rasterization operation from the OPC process and more broadly from the entire computational lithography (CL) pipeline. This enables more precise lithography simulations, even in cases where lithography simulations are performed on design layouts with a high degree of complexity, e.g., design layouts for curvilinear masks.

Third, the differentiable OPC process 125 is a fully differentiable workflow that allows gradient-based optimization to be applied to layout data based on optimization a loss function. By making all steps in the OPC process differentiable, implementations of the differentiable OPC process 125 allows layout corrections to directly and holistically account for lithography simulation results at the edges of the layout, rather than relying on local adjustments. Accordingly, an OPC system described in this disclosure can generate a final layout that has a high accuracy over many fewer iterations than some existing OPC systems. Therefore, the OPC system described in this disclosure may consume fewer computational resources (e.g., memory, computing power, or both) than some existing OPC systems when generating final layouts that have a comparable accuracy.

As shown in FIG. 1, the differentiable OPC workflow 125 includes four stages: an optical simulation stage 130, a resist simulation stage 140, a contouring stage 150, and a correction stage 160. Notably, none of these four stages involves any rasterization operation.

At the optical simulation stage 130, an aerial image is generated from the retargeted design layout 122. An aerial image includes intensity values (also referred to herein as aerial image intensity values) that represent the radiation intensity distribution (also referred to herein as the intensity distribution of light) at substrate level. The aerial image intensity values in the aerial image are dependent on the optical properties of the lithographic projection apparatus, e.g., properties of the illumination (e.g., pupil plane of the illuminator), the patterning device, and the projection optics.

In some implementations, the aerial image includes a plurality of pixels that correspond respectively to a plurality of spatial domain coordinates. Each of the plurality of pixels has an associated numerical value. The numerical value indicates an amount of light intensity at the corresponding pixel or the corresponding spatial coordinate (e.g., during the photolithography process).

While an etching process is undertaken, a speed in which an etching target layer exposed by a mask pattern is removed (e.g., an amount, a shape, and the like) may be affected by an angle of inclination (a slope) formed by a cross-section of the mask pattern with an upper surface of the etching target layer. The angle of inclination of the cross-section of the mask pattern may be determined by characteristics of illumination (i.e., light) used when a photoresist layer is exposed in order to form the mask pattern, for example, an intensity distribution of the light. The intensity distribution of light may be expressed as an aerial image.

In some implementations, Hopkin's method can be used as part of the optical simulation stage 130 to generate the aerial image for an illumination source of a given optical system based on the retargeted design layout 122. The Hopkin's method uses a set of transmission cross coefficients (TCCs) for calculating the aerial image intensity values. More specifically, the Hopkin's method is based on the exchange of the integration order over the point source contributions and the diffraction amplitudes, which has the advantage that the given optical system with fixed illumination, numerical aperture, defocus, and other aberrations can be defined using the transmission cross coefficients (TCCs).

In some implementations, the transmission cross coefficients (TCCs) can be either given or predetermined in accordance with an illumination pupil and a projection pupil corresponding to the illumination source of the given optical system, but independently of the target pattern itself. Once computed, they can be reused for repeated aerial image simulations of different target patterns printed by the same optical system.

In the Hopkin's method, to apply n TCCs to the retargeted design layout 122, one forward frequency transform and n inverse frequency transforms may be used in some implementations. The results of the inverse Fourier transforms are squared and summed to provide the aerial image intensity values.

In some implementations, the results of the inverse Fourier transforms are summed in accordance with sum of coherent systems (SOCS). The sum of coherent sums (SOCS) operation can be used to compute the aerial image when taking into account multiple eigenvalues that correspond respectively to different types of illuminations (e.g., quasar, annular, and conventional illuminations) that can be formed from the set of TCCs. For example, the multiple eigenvalues can be obtained by diagonalizing a TCC matrix by way of singular value decomposition (SVD).

In accordance with the implementations of the present disclosure, the forward frequency transform can be a boundary Fourier transform (BFT), and each inverse frequency transform can be an inverse fast Fourier transform (iFFT). As will be described further below, the use of the boundary Fourier transform (BFT) enables the calculation of the aerial image intensity values in the aerial image from the retargeted design layout 122, which may be represented in data that has a vector graphic format, without any rasterization operation.

At the resist simulation stage 140, a resist image is generated from the aerial image that is generated as a result of the optical simulation stage 130. A layer of radiation-sensitive material (also referred to herein as a resist layer) on the substrate is exposed and the aerial image is transferred to the resist layer as a resist image therein. A resist image includes intensity values (also referred to herein as resist image intensity values) that represent a spatial distribution of solubility of the resist in the resist layer. A variety of suitable techniques can be used to calculate the resist image intensity values from the aerial image.

In some implementations, a resist model can be used during the resist simulation stage 140 to determine the resist image intensity values. For example, the resist model can calculate the resist image intensity values by evaluating a function of the resist image intensity values in accordance with parameters of the resist model. Example parameters of the resist model include those that describe properties of the resist layer, e.g., the effects of chemical processes which occur during resist exposure, post exposure bake (including acid inhibitor reaction, acid base neutralization, and diffusion of various chemical species), and development.

In some implementations, a machine learning model can be used during the resist simulation stage 140 to determine the resist image intensity values. The machine learning model can be a machine learning model with an appropriate architecture that allows the neural network to process a model input that includes the aerial image and possibly other data to generate a model input that includes or otherwise specifies the resist image.

For example, the neural network can include one or more convolutional layers, one or more feed-forward layers, one or more self-attention layers, or other suitable types of layers. A specific example of such a neural network that can be used to generate resist images based on aerial images is the convolutional neural network described in U.S. Patent Application Publication No. 2024/0036478A1, the disclosure of which is hereby incorporated by reference in its entirety.

In some implementations, the resist image has the same pixel dimensions as the aerial image. That is, the resist image includes the same number of pixels as the aerial image that correspond respectively to the same plurality of spatial domain coordinates. Each of the plurality of pixels has an associated numerical value. The numerical value indicates a solubility of the resist at the corresponding pixel or the corresponding spatial coordinate (e.g., during a chemical process).

At the contouring stage 150, a contour in the resist image (also referred to herein as a resist image contour) is generated based on the resist image that is generated as a result of the resist simulation stage 140. For example, the resist image contour can represent a contour of the target pattern. A variety of suitable contouring techniques can be used to extract the resist image contour from the resist image.

In some implementations, the resist image contour can be determined by thresholding. Specifically, the resist image contour can be determined by comparing the resist image intensity values to a predetermined threshold value, e.g., by finding contour lines such that the difference between resist image intensity values and the predetermined threshold values T at all control points (or evaluation points) are equal to zero.

A design layout, e.g., the initial design layout 110 or the retargeted design layout 122, can have been partitioned into edge segments and control points can have been assigned to distinct locations along each edge segment. The assignment of the control points can be dependent on the geometries included in the design layout, the transmission cross coefficients (TCCs) used during the optical simulation stage 130, and so on.

In some implementations, a differentiable contouring algorithm can be used to generate the resist image contour. One example of such a differentiable contouring algorithm is the marching squares algorithm that can be used to generate boundaries in a two-dimensional (2D) dimension.

In some implementations, a machine learning model can be used during the contouring stage 150 to generate the resist image contour. For example, the machine learning model can be a neural network with an appropriate architecture that allows the neural network to process a model input that includes the resist image and possibly other data to generate a model output that includes or otherwise specifies the resist image contour.

For example, the neural network can include one or more convolutional layers, one or more feed-forward layers, one or more self-attention layers, or any other types of layers. A specific example of such a neural network that can be used to predict resist image contours from resist images is the convolutional neural network described in U.S. Patent Application Publication No. 2024/0168372A1, the disclosure of which is hereby incorporated by reference in its entirety.

To preserve the differentiability of the overall differentiable OPC workflow 125, prior to using these contouring techniques, the contouring stage 150 includes performing a forward frequency transform and an inverse frequency transform to convert the resist image from a discrete space to a continuous space. Then, a contouring technique can be used to generate the resist image contour from the resist image in the continuous space.

In accordance with the implementations of the present disclosure, the forward frequency transform can be a fast Fourier transform (FFT) or discrete Fourier transform (DFT) that uses only amplitude coefficients and not phase coefficients, thereby avoiding phase ambiguity during the conversion to the continuous space, and the inverse frequency transform can be an inverse discrete Fourier transform (iDFT).

When initially generated as a result of the resist simulation stage 140, the resist image is in a discrete space, such that the resist image includes resist image intensity values at a discrete set of spatial domain coordinates, e.g., at coordinates of a design grid of a finite number of points in space. That is, the resist image only includes resist image intensity values on the design grid, and does not include any resist image intensity values off the design grid.

For example, the resist image in the discrete space can include a resist image intensity value at a grid point (0.0, 0.1) and a resist image intensity value at a neighbor grid point (0.0, 0.2), but does not include resist image intensity values at any of the intermediate spatial domain coordinates in between the two neighbor grid points, e.g., at (0.1, 0.11).

In contrast, the resist image in the continuous space can include resist image intensity values at a continuous set of spatial domain coordinates, e.g., at coordinates of any possible points in space, and not just on the design grid. For example, the resist image in the continuous space can include a resist image intensity value at a point (0.0, 0.1) and a resist image intensity value at another point (0.0, 0.2), and can further include resist image intensity values at any of the intermediate spatial domain coordinates in between the two points, e.g., at (0.1, 0.11).

At the correction stage 160, the OPC design layout 162 is generated by modifying the retargeted design layout 122, such that the contour of the target pattern represented by the resist image contour is close enough to an edge of the target pattern. As will be described further below, because the entire OPC process 125 is differentiable, the retargeted design layout 122 can be modified across a plurality of iterations by using a gradient-based optimization technique and, more specifically by, at each iteration, backpropagation of gradients of an edge placement error (EPE) loss function 161, which measures a difference between the contour of the target pattern and the edge of the target pattern.

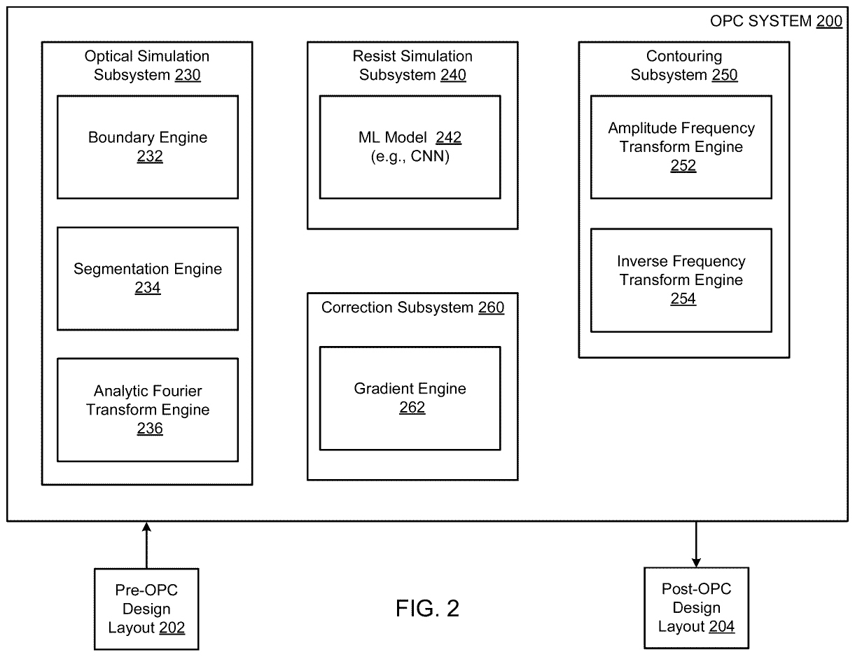

FIG. 2 is a block diagram illustrating an example computer system 200 (also referred to herein as the optical proximity correction (OPC) system 200) that may be configured to perform operations included in a differentiable optical proximity correction (OPC) process, e.g., operations included in the differentiable OPC workflow 125 of FIG. 1.

At a high level, the differentiable OPC system 200 receives a pre-OPC design layout 202 and processes the pre-OPC design layout 202 to generate a post-OPC design layout 204. For example, the pre-OPC design layout 202 can correspond to the retargeted design layout 122 of FIG. 1, while the post-OPC design layout 204 can correspond to the OPC design layout 162 of FIG. 1.

The OPC system 200 includes an optical simulation subsystem 230 that is configured to perform operations for optical simulation, e.g., operations included in the optical simulation stage 130 of the differentiable OPC workflow 125 of FIG. 1. The OPC system 200 includes a resist simulation subsystem 240 that is configured to perform operations for resist simulation, e.g., operations included in the resist simulation stage 140 of the differentiable OPC workflow 125 of FIG. 1. The OPC system 200 includes a contouring subsystem 250 that is configured to perform operations for contouring, e.g., operations included in the contouring stage 150 of the differentiable OPC workflow 125 of FIG. 1. Further, the OPC system 200 includes a correction subsystem 260 that is configured to perform operations for the adjustment of the pre-OPC design layout, e.g., operations included in the correction stage 160 of the differentiable OPC workflow 125 of FIG. 1.

While the optical simulation subsystem 230, the resist simulation subsystem 240, and the contouring subsystem 250 are illustrated as collocated in the same OPC system 200 in FIG. 2, this is not required in all implementations. In some implementations, the subsystems 230, 240, and 250 be hosted on separate computing systems in separate geographical locations.

The optical simulation subsystem 230 is configured to generate an aerial image based on the pre-OPC design layout 202. To that end, the optical simulation subsystem 230 includes a boundary engine 232, a segmentation engine 234, and an analytic Fourier transform engine 236.

The boundary engine 232 is configured to generate boundary data for a pre-OPC design layout by extracting the edge information from the pre-OPC design layout, which includes geometries represented in a vector graphic format (e.g., that includes spatial domain coordinates). The boundary data defines a boundary of each of a plurality of geometries.

For example, the pre-OPC design layout can define, for each of a plurality of geometries included in the pre-OPC design layout, spatial domain coordinates for a set of vertices along an outline of the geometry, and the boundary engine 232 is configured to determine the boundary of the geometry by connecting the set of vertices along the outline of the geometry.

For each of the plurality of geometries included in the pre-OPC design layout, the segmentation engine 234 can generate a plurality of boundary segments based on a boundary of the geometry. Each boundary segment is a linear segment (i.e., a straight line segment). As mentioned previously, the plurality of geometries can include any of a variety of geometries, and the boundary engine 232 can generate the boundary data for different geometries in different ways, depending on the shapes of the geometries.

For any geometry that has a polygon shape, this can be done by partitioning the boundary of the geometry into the plurality of boundary segments. Each boundary segment can be a linear segment (i.e., a straight line segment) which is a fragment of the outline of the polygon. When connected end-to-end, the linear segments form the boundary of the polygon shape. Examples of polygon shapes include squares, rectangles, triangles, and so on.

Alternatively, for any geometry that has a curved shape, the plurality of boundary segments can each be a linear segment which, when connected end-to-end, form a piecewise linear approximation of the boundary of the curved shape. Examples of curved shapes include circles, ellipses, and so on.

In some implementations, when a geometry that has a curved shape, the segmentation engine 234 can generate a piecewise linear approximation of a boundary of the curved shape by partitioning the boundary of the curved shape into a plurality of segments and, for any segment that has a curved shape, generating one or more linear segments (i.e., a straight line segments) that correspond to an approximated representation of the curved shape and that will replace the segment that has the curved shape. By doing so, the segmentation engine 234 can generate a plurality of linear segments that approximate an arc (e.g., a rounded corner of a square), for example.

The optical simulation subsystem 230 can use the analytic Fourier transform engine 236 to apply a forward frequency transform when generating an aerial image based on the pre-OPC design layout using Hopkin's method, as mentioned herein.

In particular, the analytic Fourier transform engine 236 is configured to apply a boundary Fourier transform (BFT) on the pre-OPC design layout to transform the pre-OPC design layout from a spatial domain into a frequency domain, i.e., generate a frequency domain representation of pre-OPC design layout.

For example, the analytic Fourier transform engine 236 can apply the boundary Fourier transform (BFT) based on analytically computing the following equation:

$${m}_{pq} = \frac{i}{2 Π {L}^{2}} {\sum }_{{Ω}_{l}} ( Δ \vec{x} \times {\vec{f}}_{pq}^{*} ) \cdot \hat{z} {e}^{- i 2 Π {\vec{x}}_{c} \cdot {\vec{f}}_{pq}} sin c ( Δ \vec{x} \cdot {\vec{f}}_{pq} ) ,$$

where \vec{x} represents spatial domain coordinates, \vec{f} represents frequency domain coordinates, \vec{f}*=\vec{f}/∥f∥² represents the normalized frequency domain coordinates (normalized by its squared magnitude), Ω represents a linear segment that is defined by endpoints \vec{P₀}=(x₀, y₀) and \vec{P₁}=(x₁, y₁), the frequency domain is discretized into units of 1/L (e.g., units of nanometers), and p and q are integers corresponding to this discretization.

Using the equation above allows for the analytic Fourier transform engine 236 to generate the frequency domain representation of pre-OPC design layout by computing a one-dimensional (1D) line integral for each linear segment Ω along a boundary of a geometry in place of a two-dimensional (2D) area integral.

In particular, as part of the boundary Fourier transform (BFT), the analytic Fourier transform engine 236 uses integration by parts and the normal vectors of the plurality of boundary segments that have been generated by the segmentation engine 234 for each of the plurality of geometries included in the pre-OPC design layout to transform the 2D area integrals that would otherwise be required in the computations for a standard Fourier transform into 1D line integrals.

The normal vector, often simply called the normal, to a boundary segment, is a vector which is perpendicular to the boundary segment at a given point along the boundary segment. The fact that these boundary segments are generated as a linear segment (i.e., a straight line segment) by the segmentation engine 234, facilitates the calculation of these normal vectors as part of the boundary Fourier transform (BFT) being performed by analytic Fourier transform engine 236.

For example, a standard Fourier transform can be applied by computing the following equation:

$$m ( \vec{f} ) = \frac{1}{{L}^{2}} \int M ( \vec{x} ) {e}^{- i 2 π \vec{x} \cdot \vec{f}} d \vec{x} ,$$

where \vec{x} represents spatial domain coordinates, \vec{f} represents frequency domain coordinates, M(\vec{x}) is a function that represents the pre-OPC design layout in a vector graphic format, where it equals 1 inside the geometry and 0 outside.

Using integration by parts, this equation for a standard Fourier transform can be rewritten as:

$$m ( \vec{f} ) = \frac{1}{2 Π {iL}^{2}} \int ∇ M ( \vec{x} ) \cdot {\vec{f}}^{*} {e}^{- i 2 π \vec{x} \cdot \vec{f}} d \vec{x} ,$$

where \vec{f}*=\vec{f}/∥\vec{f}∥² represents the normalized frequency domain coordinates (normalized by its squared magnitude), the gradient ∇M(\vec{x}) exists only at the linear segment Ω of a boundary of a geometry, where it is represented by a delta function −δ(\vec{x}−\vec{x}_{Ω})\hat{n}_{Ω}, where \hat{n}_{Ω} represents the normal vector with respect to the linear segment Ω. The 2D area integrals can then be transformed into 1D line integrals along the boundary:

$$m ( \vec{f} ) = \frac{i}{2 {Π}^{2}} {\int }_{Ω} {\hat{n}}_{Ω} \cdot {\vec{f}}^{*} {e}^{- i 2 Π \vec{x} \cdot \vec{f}} {dl}_{Ω} .$$

By applying the boundary Fourier transform (BFT), the pre-OPC design layout in the spatial domain can be directly transformed into the frequency domain, effectively allowing the optical simulation subsystem 230 to calculate the aerial image intensity values in the aerial image together with using other components (e.g., an optical model that stores the transmission cross coefficients (TCCs), an inverse Fourier transform engine, and a summation engine) included in or accessibly by the optical simulation subsystem 230, without any rasterization operation.

The resist simulation subsystem 240 is configured to generate a resist image based on the aerial image. To that end, the resist simulation subsystem 240 includes a machine learning model 242, which can be used to determine the resist image intensity values included in the resist image. For example, the machine learning model 242 can be the convolutional neural network that is mentioned above.

The contouring subsystem 250 is configured to generate a resist image contour based on the resist image. As mentioned herein, when initially generated as output by the resist simulation subsystem 240, the resist image is in a discrete space, such that the resist image includes resist image intensity values at a discrete set of spatial domain coordinates. The contouring subsystem 250 uses an amplitude frequency transform engine 252 and an inverse frequency transform engine 254 to convert the resist image from the discrete space to a continuous space.

The amplitude frequency transform engine 252 is configured to apply a forward frequency transform on the resist image to generate a frequency domain representation of the resist image. For example, the forward frequency transform can be a fast Fourier transform (FFT). As another example, the forward frequency transform can be a discrete Fourier transform (DFT).

In particular, the forward frequency transform uses only amplitude coefficients and not phase coefficients of the resist image intensity values included in the resist image, thereby avoiding phase ambiguity during the conversion to the continuous space. In some implementations, the forward frequency transform uses the square root of the amplitude coefficients instead of the raw intensity.

The inverse frequency transform engine 254 is configured to apply an inverse frequency transform on the frequency domain representation of the resist image to generate a restored representation of resist image in the spatial domain. For example, the inverse frequency transform can be an inverse discrete Fourier transform (iDFT). When applied, the inverse discrete Fourier transform (iDFT) outputs amplitude coefficients at a continuous set of spatial domain coordinates.

The contouring subsystem 250 can then generate a resist image in a continuous space (also referred to herein as a continuous resist image) from the restored representation of resist image in the spatial domain. For example, these amplitude coefficients at the continuous set of spatial domain coordinates can be processed, e.g., squared, to restore the resist image intensity values, enabling the generation of the continuous resist image that include resist image intensity values at the continuous set of spatial domain coordinates, e.g., at coordinates of any possible points in space, and not just on the design grid.

Then, the contouring subsystem 250 generates a resist image contour based on the continuous resist image by using a contouring technique. The contouring technique can be one of the example contouring techniques mentioned herein, and possibly other known contouring techniques. The resist image contour represents a contour of the target pattern.

The correction subsystem 260 includes a gradient engine 262. The correction subsystem 260 is configured to generate the post-OPC design layout by iteratively modifying the pre-OPC design layout, such that the contour of the target pattern represented by the resist image contour is as close as possible to an edge of the target pattern based on gradients of an edge placement error (EPE) loss function that are computed by using the gradient engine 262 with respect to the resist image contour at each iteration.

Leveraging the differentiability of the differentiable OPC process, at each iteration, the computed gradients can then be backpropagated through the pixels of the resist image, and further through the pixels of the optical image, to determine the modifications to the pre-OPC design layout.

The EPE loss function can be any suitable appropriate loss function that measures a difference between the contour of the target pattern and the edge of the target pattern. For example, the EPE loss function can be a mean squared error (MSE) loss function. As another example, the EPE loss function can be a mean absolute error (MAE) loss function. As another example, the EPE loss function can be a mean absolute deviation (MAD) loss function.

A large EPE loss generally indicates a significant amount of difference between the contour of the target pattern and the edge of the target pattern, such that a design layout of a mask may not be suitable to form the target pattern. Accordingly, to obtain a design layout of the mask that is appropriate to form the target pattern, the EPE loss will need to be reduced, e.g., to a predetermined loss value or less, by applying gradient-based modifications to the design layout through backpropagation.

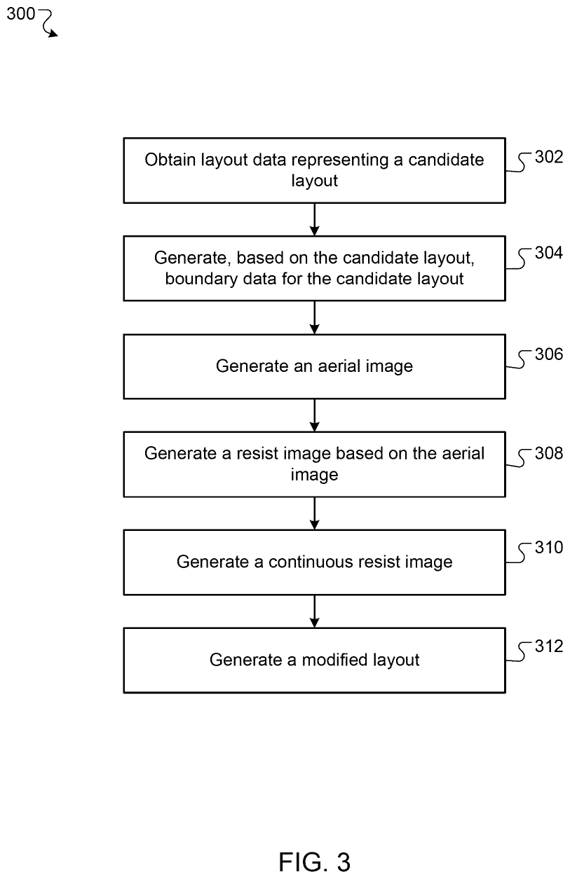

FIG. 3 is a flow diagram of an example process 300 for differentiable optical proximity correction (OPC). In some implementations, steps of process 300 are enabled by programmed firmware or software instructions, which are executable by one or more processors of the computer systems described in this document. For example, steps of process 300 can be implemented or executed using the OPC system 200 described above.

Each iteration of process 300 can correspond to one of a plurality of iterations for modifying a pre-OPC design layout (e.g., the retargeted design layout 122 of FIG. 1) as part of the differentiable optical proximity correction (OPC) process 125 discussed above with reference to FIG. 1.

When appropriately programmed in accordance with this specification, a computer system can repeatedly perform iterations of process 300 to iteratively modify the pre-OPC design layout to generate a post-OPC design layout (e.g., the OPC design layout 162 of FIG. 1). Thus, in the example of FIG. 1, the retargeted design layout 122 of FIG. 1 can be obtained prior to the first iteration of process 300, and the OPC design layout 162 of FIG. 1 can be generated after the last iteration of process 300.

The computer system can continue performing iterations of process 300 until termination criteria for the differentiable optical proximity correction (OPC) process have been satisfied, e.g., until a EPE loss have converged, until a threshold amount of wall clock time has elapsed, or until a threshold number of iterations of process 300 have been performed.

The process 300 includes obtaining layout data representing a candidate layout corresponding to a target pattern (302). The target pattern may be, e.g., a circuit pattern to be formed on a substrate (e.g., a wafer or another material surface) through an exposure process using a mask. The candidate layout may be, for example, a design layout of a mask pattern to be formed on the mask to form the target pattern.

For the first iteration of process 300, the candidate layout can correspond to the retargeted design layout 122 of FIG. 1. For any subsequent iteration of process 300, the candidate layout can correspond to the modified layout that has been generated in the immediately preceding iteration of process 300.

The candidate layout can include a plurality of geometries, e.g., geometries that have curved shapes, or geometries that have polygon shapes such as squares, rectangles, or triangles, or both. For example, the layout data can have a vector graphic format such as a Graphic Data System II (GDSII) format, an Open Artwork System Interchange Standard (OASIS) format, or another data format.

The process 300 includes generating, based on the spatial domain coordinates for a set of vertices included in the layout data, boundary data for the candidate layout (304). The boundary data defines a boundary of each of the plurality of geometries included in the candidate layout. For each geometry, the boundary represents an outline (or border) of the geometry.

The process 300 includes generating an aerial image based on the layout data, which can be in a vector graphic format, using the Hopkin's method (306). An aerial image includes aerial image intensity values that represent the radiation intensity distribution (the intensity distribution of light) at substrate level. Using the Hopkin's method to generate the aerial image involves applying a forward frequency transform on the candidate layout and then applying one or more inverse frequency transforms.

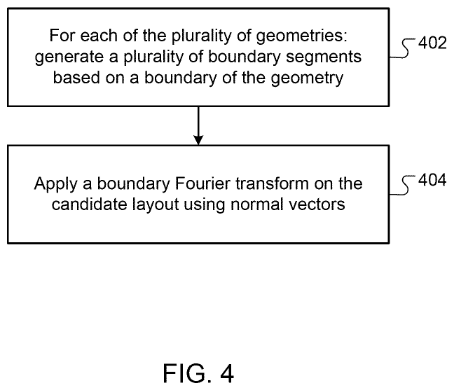

In particular, the forward frequency transform is a boundary Fourier transform which can generate a frequency domain representation of the candidate layout based on using normal vectors with respect to the boundary of each of the plurality of geometries. Applying the boundary Fourier transform is explained in more detail with reference to FIG. 4, which shows sub-steps 402-404 of step 306.

Referring to FIG. 4, for each of the plurality of geometries, a plurality of boundary segments is generated based on a boundary of the geometry (402). Each boundary segment is a linear segment (i.e., a straight line segment). For any geometry that has a polygon shape, the plurality of boundary segments can each be a fragment of the outline of the polygon. Alternatively, for any geometry that has a curved shape, the plurality of boundary segments can each be a linear segment which, when connected end-to-end, form a piecewise linear approximation of the boundary of the curved shape.

The boundary Fourier transform is applied on the candidate layout using normal vectors with respect to the plurality of boundary segments generated for each of the plurality of geometries (404). For example, the plurality of boundary segments can include boundary segments that are fragments of an outline of each of one or more geometries that has a polygon shape, and can further include boundary segments that form a piecewise linear approximation of each of one or more geometries that has a curved shape.

As described above with reference to the analytic Fourier transform engine 236 of FIG. 2, applying the boundary Fourier transform involves analytically computing the boundary Fourier transform by, for each of the plurality of geometries, computing a line integral for each of the plurality of linear segments included in the boundary of the geometry.

Referring back to FIG. 3, the process 300 includes generating a resist image based on the aerial image (which, in turn, is generated based on the frequency domain representation of the candidate layout) (308). The resist image includes resist image intensity values that represent a spatial distribution of solubility of the resist in the resist layer. The resist image intensity values can be calculated from the aerial image by using any of a variety of techniques, e.g., by using a resist model or a machine learning model, e.g., a convolutional neural network.

Initially, at step 308, the resist image is generated in a discrete space, such that the resist image includes resist image intensity values at a discrete (i.e., finite) set of spatial domain coordinates. The process 300 then includes converting the resist image from the discrete space to a continuous space, i.e., includes generating a continuous resist image (310).

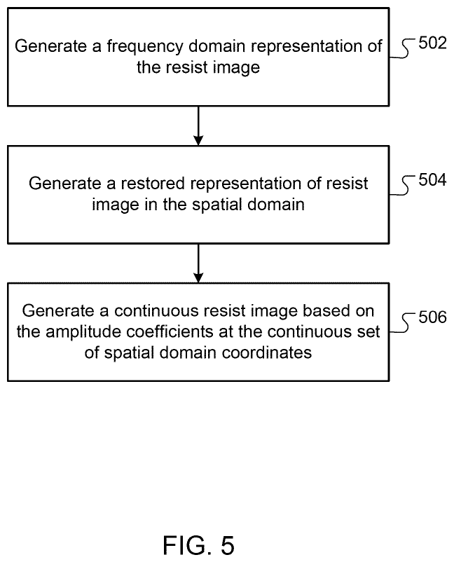

The continuous resist image includes resist image intensity values at a continuous (i.e., infinite) set of spatial domain coordinates. The conversion of the resist image from the discrete space to the continuous space is explained in more detail with reference to FIG. 5, which shows sub-steps 502-506 of step 310.

Referring now to FIG. 5, a forward frequency transform is applied on the resist image intensity values to generate a frequency domain representation of the resist image (502). In particular, the forward frequency transform uses only amplitude coefficients and not phase coefficients of the resist image intensity values included in the resist image. For example, the forward frequency transform can be a fast Fourier transform (FFT). As another example, the forward frequency transform can be a discrete Fourier transform (DFT).

An inverse frequency transform is applied on the frequency domain representation of the resist image to generate a restored representation of resist image in the spatial domain (504). For example, the inverse frequency transform can be an inverse discrete Fourier transform (iDFT). When applied, the inverse discrete Fourier transform (iDFT) outputs amplitude coefficients at a continuous set of spatial domain coordinates.

The continuous resist image is generated based on the amplitude coefficients at the continuous set of spatial domain coordinates (506). For example, these amplitude coefficients at the continuous set of spatial domain coordinates can be processed, e.g., squared, to restore the resist image intensity values, enabling the generation of the continuous resist image that include resist image intensity values at the continuous set of spatial domain coordinates.

Referring back to FIG. 3, the process 300 includes modifying the candidate layout to generate a modified layout based on optimizing an edge placement error (EPE) loss function (312). This can be done by computing the gradients of the EPE loss function with respect to the resist image contour and backpropagating the computed gradients through the pixels of the resist image, and further through the pixels of the optical image, to determine the modifications to the candidate layout.

The EPE loss function can be any appropriate loss function that measures a difference between a contour of the target pattern and an edge of the target pattern. As described previously, the contour of the target pattern is generated based on the continuous resist image (which, in turn, is generated based on the frequency domain representation of the resist image) by using a contouring technique.

For the last iteration of process 300, the modified layout can be used as the post-OPC design layout, which can correspond to the OPC design layout 162 of FIG. 1. For any other iteration of process 300, the modified layout can be used as the candidate layout in the immediately subsequent iteration of process 300.

After the post-OPC design layout has been generated by iteratively modifying the pre-OPC design layout as a result of repeatedly performing the iterations of process 300, the post-OPC design layout can be subsequently used in any of a variety of ways.

In some implementations, after having repeatedly performed the iterations of process 300, the computer system can output final layout data representing the modified layout corresponding to the target pattern, i.e., the post-OPC design layout, to be used to manufacture a mask. For example, the final layout data representing the post-OPC design layout can then be communicated, e.g., as Mask Tape Out (MTO) design data, to an exposure facility associated with the manufacture of mask(s) used during lithographic processes, such as photomasks, electron beam masks, etc. In this regard, the MTO design data may be understood as mask design data, as corrected and verified by a differentiable OPC process.

The MTO design data may be expressed as graphic data having a format compatible with electronic design automation (EDA) software, or the like. For example, the MTO design data may have a data format compatible with such conventionally understood software as GDS and OASIS.

After the MTO design data has been communicated, a mask data preparation (MDP) may be performed. The MDP may include, for example, format conversion referred to as fracturing, augmentation of a bar code for mechanical reading, a standard mask pattern for inspection, or a job deck, and automatic or manual verification.

After performing the MDP, a substrate for a mask is exposed based on the mask data. Exposure may indicate, for example, electronic beam writing. The electronic beam writing may be performed using, for example, a gray writing method in which a multi-beam mask writer (MBMW) is used. In addition, the electronic beam writing may also be performed using a variable shape beam (VSB) exposure apparatus.

After the exposure operation, a series of operations are performed to complete the mask. The series of operations may include, e.g., development, etching, washing, and the like. In addition, the series of operations for mask manufacturing may include measuring, defect inspection, or defect repair. In addition, a pellicle coating operation may also be included.

Ultimately, in some implementations, a semiconductor chip can be manufactured using the mask. In this regard, the semiconductor chip may be a volatile memory (e.g., a DRAM or a SRAM); a nonvolatile memory (e.g., flash memory); or a logic semiconductor (e.g., a microprocessor, such as a CPU, a controller, an application specific integrated circuit (ASIC) or the like).

The semiconductor chip can be manufactured by repeatedly performing processes that form additional patterns on a lower structure. Those skilled in the art will further understand that a semiconductor chip may be fully manufactured by performing a sequence of various processes, such as depositions, etchings, ion implantation, cleaning, etc. As part of these processes, one or more lithography processes—making use of mask(s) manufactured in accordance with the post-OPC design layout generated by using the differentiable OPC process described in this specification—may be applied.

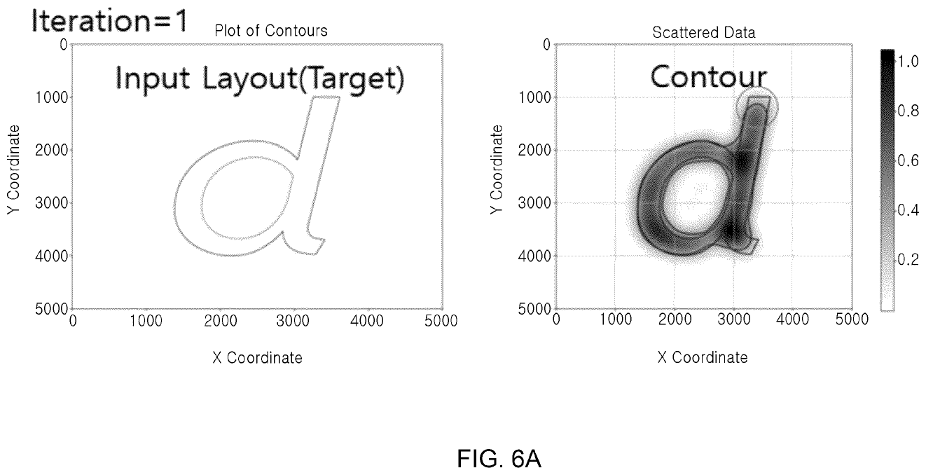

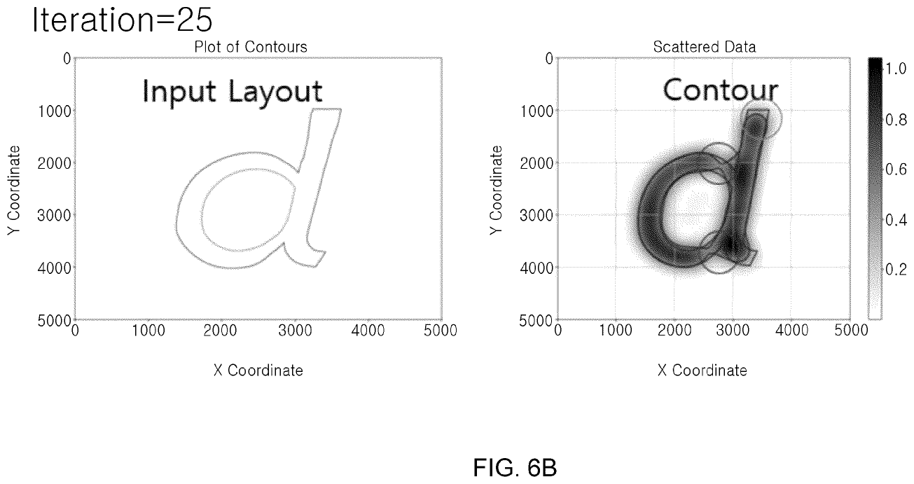

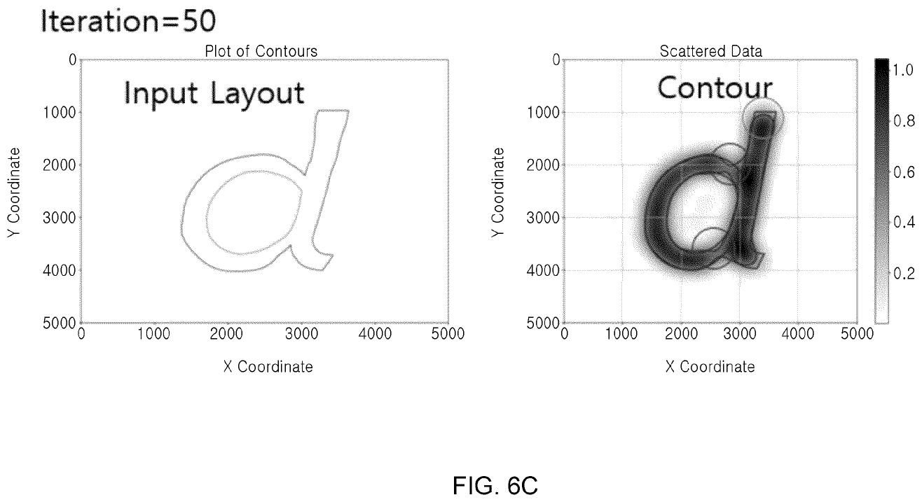

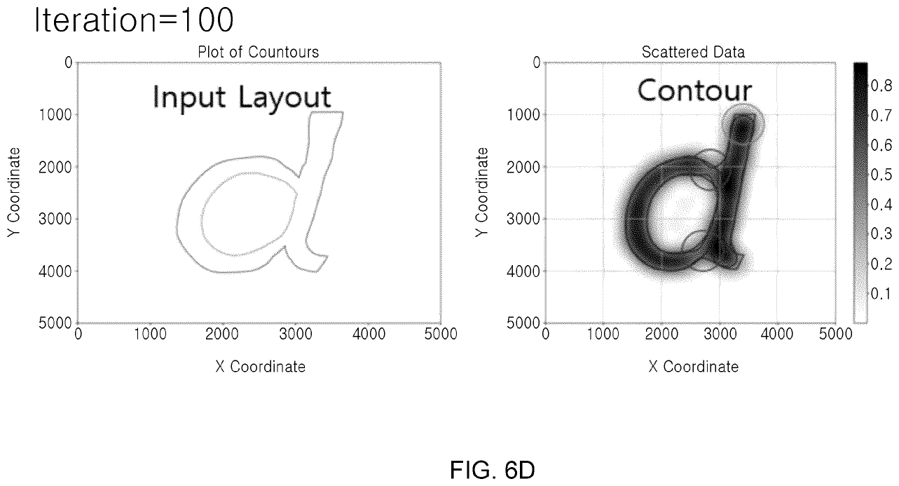

FIG. 6A-D show examples of illustrations of an edge of a target pattern and a contour of the target pattern at the 1^{st} iteration, 25^{th} iteration, 50^{th} iteration, and the 100^{th} iteration, respectively, of the process 300 for differentiable optical proximity correction (OPC), as discussed above with reference to FIG. 3.

In FIG. 6A, at the 1^{st} iteration, the contour of the target pattern (illustrated as the inner borderline) shows significant differences in size and line-end placement (as indicated by the circles) compared to the edge of the target pattern (illustrated as the outer borderline). As iterations of the process 300 progress, the size of the contour of the target pattern approaches the size of the edge of the target pattern, and line-end alignment also improves.

In particular, the gradient-based optimization allows the contour of the target pattern to approach very quickly toward the edge of the target pattern as the iterations progress. For example, FIG. 6C shows that, at the 50^{th} iteration, the size of the contour of the target pattern already has very limited difference compared to the size of the edge of the target pattern, and has significantly improved line-end alignment relative to the 1^{st} iteration shown in FIG. 6A.

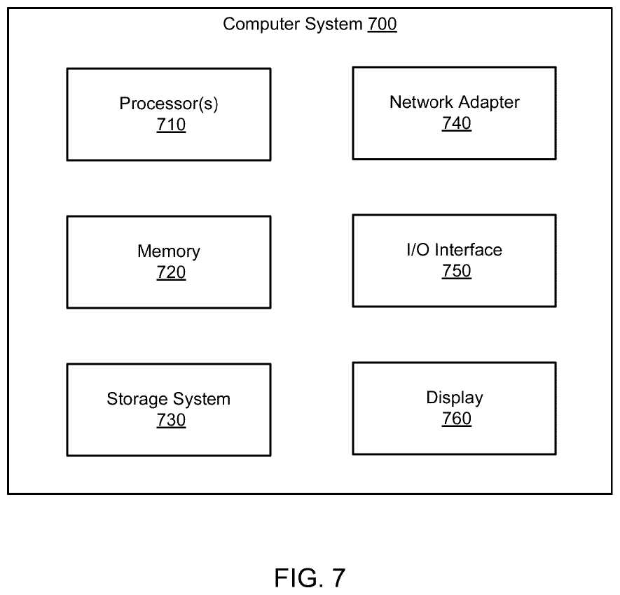

FIG. 7 is a block diagram illustrating an example of a computer system 700 for implementing the present disclosure. In some implementations, the computer system 700 of FIG. 7 is configured to execute the differentiable OPC process described in this specification, for example, to implement the OPC system 200 as described with respect to FIG. 2, or to perform steps of process 300 as described with respect to FIG. 3.

The computer system 700 may refer to any system including a general purpose or special purpose computing system. For example, the computer system 700 may include a personal computer, a server computer, a laptop computer, a home appliance, and the like. As shown in FIG. 7, the computer system 700 may include at least one processor 710, a memory 720, a storage system 730, a network adapter 740, an input/output (I/O) interface 750, and a display 760.

The at least one processor 710 may execute a program module including computer system executable instructions. The program module may include routines, programs, objects, components, logic, data structures, and the like, performing a specific task or implementing a specific abstract data type. The memory 720 may include a computer system readable, non-transitory medium in the form of a volatile memory such as a random access memory (RAM). The at least one processor 710 may access the memory 720 and execute instructions loaded in the memory 720. The storage system 730 may non-volatilely store information and may include at least one program product including a program module configured to perform inference and/or training by executing and/or otherwise using the deep learning networks described herein. A program may include, by way of non-limiting examples, an operating system, at least one application, other program modules, and program data.

The network adapter 740 may provide a connection to a local area network (LAN), a wide area network (WAN), and/or a public network (e.g., the Internet), etc. The I/O interface 750 may provide a communication channel with a peripheral device such as a keyboard, a pointing device, and an audio system. The display 760 may output various pieces of information so that the user may check the information.

In some implementations, the processes disclosed above are implemented as a computer program product. The computer program product may include a non-transitory computer-readable medium (or storage medium) including computer-readable program instructions for causing the at least one processor 710 to perform image processing and/or training of models. Computer readable instructions may be, but are not limited to, assembler instructions, instruction set architecture (ISA) instructions, machine instructions, machine dependent instructions, microcode, firmware instructions, state setup data, or source code or object code written in at least one programming language.

The computer-readable medium may be any type of medium capable of non-transitorily holding and storing instructions executed by the at least one processor 710 or any instruction executable device. The computer-readable medium may be an electronic storage device, a magnetic storage device, an optical storage device, an electromagnetic storage device, a semiconductor storage device, or any combination thereof, but is not limited thereto. For example, the computer readable medium may be a portable computer diskette, a hard disk, a random access memory (RAM), a read-only memory (ROM), an electrically erasable read only memory (EEPROM), a flash memory, a static random access memory (SRAM), a compact disc (CD), a digital versatile disc (DVD), a memory stick, a floppy disk, a mechanically encoded device such as a punch card, or any combination thereof.

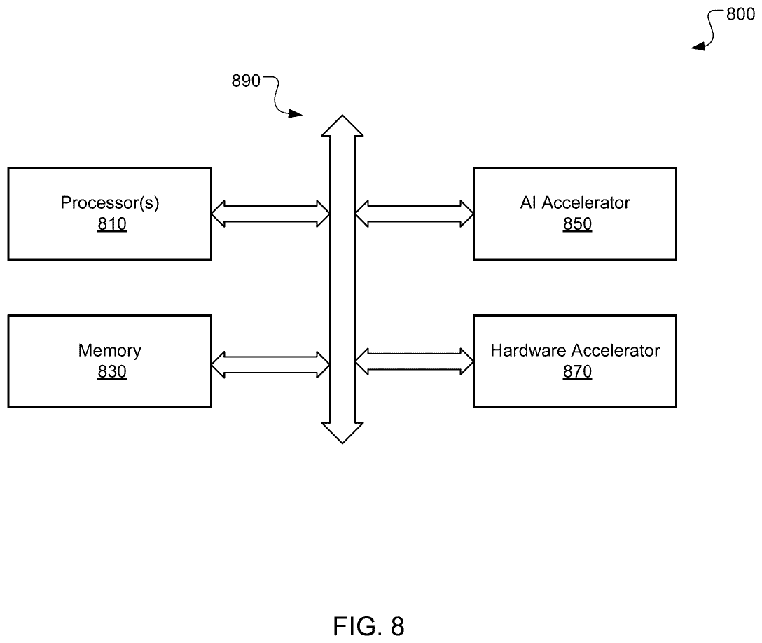

FIG. 8 is a diagram illustrating an example of a computer system 800 that includes an artificial intelligence (AI) accelerator for implementing the present disclosure. In some implementations, the differentiable OPC process described in this specification may be executed in or by the system 800.

Referring to FIG. 8, the system 800 may include at least one processor 810, a memory 830, an artificial intelligence (AI) accelerator 850, and a hardware (HW) accelerator 870, and the at least one processor 810, the memory 830, the AI accelerator 850, and the HW accelerator 870 may communicate with each other through a bus 890. In some implementations, the at least one processor 810, the memory 830, the AI accelerator 850, and the HW accelerator 870 are included in one semiconductor chip. Furthermore, in some implementations, at least two of the at least one processor 810, the memory 830, the AI accelerator 850, and the HW accelerator 870 are included in two or more semiconductor chips mounted on a board, respectively.

The at least one processor 810 may execute instructions. For example, the at least one processor 810 may execute an operating system by executing instructions stored in the memory 830, or may execute applications executed on the operating system. In some implementations, at least one processor 810 instructs the AI accelerator 850 and/or the HW accelerator 870 to perform a task by executing instructions, and may obtain a result of performing the task from the AI accelerator 850 and/or the HW accelerator 870. In some implementations, the at least one processor 810 is an application specific instruction set processor (ASIP) customized for a specific purpose, and may also support a dedicated instruction set.

The memory 830 may have an arbitrary structure for storing data. For example, the memory 830 may include a volatile memory device such as a dynamic random access memory (DRAM) or a static random access memory (SRAM), or a non-volatile memory device such as a flash memory or a resistive random access memory (RRAM). The at least one processor 810, the AI accelerator 850, and the HW accelerator 870 may store data in the memory 830 or read data from the memory 830 through the bus 890.

The AI accelerator 850 may refer to hardware designed for AI applications. In some implementations, the AI accelerator 850 includes a neural processing unit (NPU) for implementing a neuromorphic structure, may generate output data by processing input data provided from the at least one processor 810 and/or the HW accelerator 870, and may provide the output data to the at least one processor 810 and/or the HW accelerator 870. In some implementations, the AI accelerator 850 is programmable and may be programmed by the at least one processor 810 and/or the HW accelerator 870.

The HW accelerator 870 may refer to hardware designed to perform a specific task at high speed. For example, the HW accelerator 870 may be designed to perform data transformation such as multiplication, addition, encoding, and decoding at high speed. The HW accelerator 870 may be programmable and may be programmed by the at least one processor 810 and/or the HW accelerator 870.

In some implementations, the AI accelerator 850 may execute the differentiable OPC process described in this specification, for example, to perform steps of process 300 as described with respect to FIG. 3. In addition, at least some of the steps performed by the AI accelerator 850 may be executed by the at least one processor 810 and/or the HW accelerator 870.

The processes and logic flows described in this document can be performed by one or more programmable processors executing one or more computer programs to perform the functions described herein. The processes and logic flows can also be performed by, and apparatus can also be implemented as special purpose logic circuitry, for example, a Field Programmable Gate Array (FPGA) or an application specific integrated circuit (ASIC).

Processors suitable for the execution of a computer program include, by way of example, both general and special purpose microprocessors, and any one or more processors of any kind of digital computer. Computer readable media suitable for storing computer program instructions and data can include all forms of nonvolatile memory, media and memory devices. The processor and the memory can be supplemented by, or incorporated in, special purpose logic circuitry.

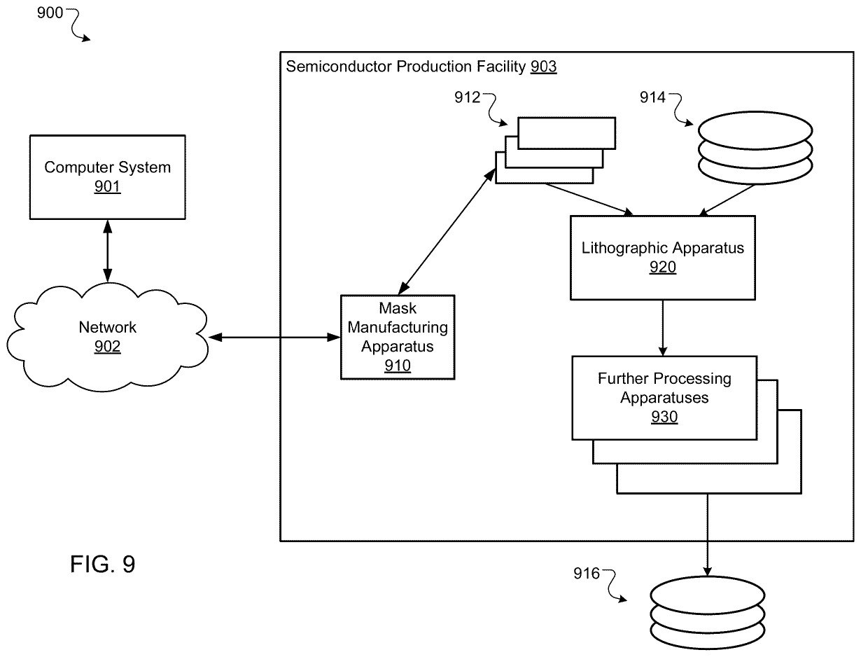

FIG. 9 is a block diagram of an example environment 900 in which differentiable optical proximity correction (OPC) can be implemented. The example environment 900 includes a network 902, such as a local area network (LAN), a wide area network (WAN), the Internet, or a combination thereof. The network 902 connects a computer system 901 and a semiconductor production facility 903 that manufactures a semiconductor chip 916.

The computer system 901 implements an optical proximity correction (OPC) system to generate a post-OPC design layout of a mask pattern and then communicates the post-OPC design layout, e.g., as Mask Tape Out (MTO) design data, over the network 902 to the semiconductor production facility 903. For example, the computer system 901 can correspond to the OPC system 200 of FIG. 2, and the computer system 901 can correspond to the computer system 700 of FIG. 7 or the computer system 800 of FIG. 8.

The semiconductor production facility 903 includes a mask manufacturing apparatus 910 that can manufacture a mask 912 that has the mask pattern in accordance with the post-OPC design layout received from the computer system 901.

The semiconductor production facility 903 also includes a lithographic apparatus 920 that applies a target pattern (e.g., a circuit pattern) onto a substrate 914 (e.g., a silicon wafer or another material surface) using the mask 912. To that end, the mask pattern of the mask 912 is transferred onto a target portion (e.g., including part of, one, or several dies) on the substrate 914 through an exposure process performed using the lithographic apparatus 920 onto a layer of radiation-sensitive material (resist) provided on the substrate 914 to form the target pattern on the substrate 914.

The semiconductor production facility 903 includes further processing apparatuses 930 that apply further processing to the substrate 914 to generate the semiconductor chip 916. Examples of these further processing apparatuses 930 includes a baking apparatus, a developing apparatus (for developing the exposed pattern into a physical resist pattern), an etching apparatus, a post-etch annealing apparatus, a metrology apparatus (for inspecting substrates), to name just a few.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A mask manufacturing method, comprising:
obtaining layout data representing a candidate layout corresponding to a target pattern, wherein the candidate layout comprises a plurality of geometries;
generating, based on the candidate layout, boundary data for the candidate layout, wherein the boundary data represents a boundary of each of the plurality of geometries;
generating a frequency domain representation of the candidate layout based on transforming the candidate layout using normal vectors with respect to the boundary of each of the plurality of geometries;
generating a modified layout based on the frequency domain representation of the candidate layout; and
outputting final layout data representing the modified layout corresponding to the target pattern to be used to manufacture a mask.

2. The method of claim 1, wherein generating the frequency domain representation of the candidate layout comprises operating directly on the layout data in a vector graphic format.

3. The method of claim 1, wherein generating the frequency domain representation of the candidate layout comprises:
for a geometry in the plurality of geometries having a curved shape, generating a piecewise linear approximation of the boundary of the geometry that comprises a plurality of linear segments that approximate the curved shape of the geometry; and
computing a Fourier transform on the candidate layout using normal vectors with respect to the plurality of linear segments included in the piecewise linear approximation generated for each of the one or more of the plurality of geometries.

4. The method of claim 3, wherein computing the Fourier transform on the candidate layout comprises:
analytically computing the Fourier transform by, for each of the one or more of the plurality of geometries, computing a line integral for each of the plurality of linear segments included in the piecewise linear approximation generated for the geometry.

5. The method of claim 1, wherein generating the modified layout based on the frequency domain representation of the candidate layout comprises:
obtaining a resist image that is generated based on the frequency domain representation of the candidate layout, wherein the resist image comprises resist image intensity values at discrete spatial coordinates;
applying a frequency transform on amplitude values of the resist image intensity values to generate a frequency domain representation of the resist image;
applying an inverse frequency transform on the frequency domain representation of the resist image to generate amplitude values at continuous spatial coordinates; and
generating, based on the amplitude values at continuous spatial coordinates, a continuous resist image that comprises resist image intensity values at the continuous spatial coordinates.

6. The method of claim 5, wherein the frequency transform comprises a discrete Fourier transform (DFT).

7. The method of claim 5, wherein the inverse frequency transform comprises an inverse discrete Fourier transform (iDFT).

8. The method of claim 5, wherein obtaining the resist image comprises:
generating an optical image based on the candidate layout;
processing the optical image using a convolutional neural network (CNN) to generate the resist image intensity values included in the resist image.

9. The method of claim 5, wherein generating the modified layout based on the frequency domain representation of the candidate layout comprises:
evaluating a loss function that measures a difference between a contour in the continuous resist image and an edge of target pattern; and
adjusting the candidate layout by backpropagation based on a gradient of the loss function.

10. The method of claim 1, wherein outputting the final layout data representing the modified layout corresponding to the target pattern to be used to manufacture the mask comprises:
transferring the final layout data as mask tape-out (MTO) design data.

11. The method of claim 10, further comprising manufacture the mask by:
preparing mask data based on the MTO design data; and
performing, based on the mask data, exposure on a substrate for the mask.

12. The method of claim 11, further comprising:
manufacturing a semiconductor chip using the mask.

13. A system comprising one or more computers and one or more storage devices storing instructions that are operable, when executed by the one or more computers, to cause the one or more computers to perform mask manufacturing operations comprising:
obtaining layout data representing a candidate layout corresponding to a target pattern, wherein the candidate layout comprises a plurality of geometries;
generating, based on the candidate layout, boundary data for the candidate layout, wherein the boundary data represents a boundary of each of the plurality of geometries;
generating a frequency domain representation of the candidate layout based on transforming the candidate layout using normal vectors with respect to the boundary of each of the plurality of geometries;
generating a modified layout based on the frequency domain representation of the candidate layout; and
outputting final layout data representing the modified layout corresponding to the target pattern to be used to manufacture a mask.

14. The system of claim 13, wherein generating the frequency domain representation of the candidate layout comprises operating directly on the layout data in a vector graphic format.

15. The system of claim 13, wherein generating the frequency domain representation of the candidate layout comprises:
for a geometry in the plurality of geometries having a curved shape, generating a piecewise linear approximation of the boundary of the geometry that comprises a plurality of linear segments that approximate the curved shape of the geometry; and
computing a Fourier transform on the candidate layout using normal vectors with respect to the plurality of linear segments included in the piecewise linear approximation generated for each of the one or more of the plurality of geometries.

16. The system of claim 15, wherein computing the Fourier transform on the candidate layout comprises:
analytically computing the Fourier transform by, for each of the one or more of the plurality of geometries, computing a line integral for each of the plurality of linear segments included in the piecewise linear approximation generated for the geometry.

17. The system of claim 13, wherein generating the modified layout based on the frequency domain representation of the candidate layout comprises:
obtaining a resist image that is generated based on the frequency domain representation of the candidate layout, wherein the resist image comprises resist image intensity values at discrete spatial coordinates;
applying a frequency transform on amplitude values of the resist image intensity values to generate a frequency domain representation of the resist image;
applying an inverse frequency transform on the frequency domain representation of the resist image to generate amplitude values at continuous spatial coordinates; and
generating, based on the amplitude values at continuous spatial coordinates, a continuous resist image that comprises resist image intensity values at the continuous spatial coordinates.

18. The system of claim 17, wherein the frequency transform comprises a discrete Fourier transform (DFT).

19. The system of claim 17, wherein the inverse frequency transform comprises an inverse discrete Fourier transform (iDFT).

20. A non-transitory computer storage medium encoded with instructions that, when executed by one or more computers, cause the one or more computers to perform mask manufacturing operations comprising:
obtaining layout data representing a candidate layout corresponding to a target pattern, wherein the candidate layout comprises a plurality of geometries;
generating, based on the candidate layout, boundary data for the candidate layout, wherein the boundary data represents a boundary of each of the plurality of geometries;
generating a frequency domain representation of the candidate layout based on transforming the candidate layout using normal vectors with respect to the boundary of each of the plurality of geometries;
generating a modified layout based on the frequency domain representation of the candidate layout; and
outputting final layout data representing the modified layout corresponding to the target pattern to be used to manufacture a mask.
